(19) United States
(12) Patent Application Publication
(10) Pub. No.: US 2023/0409781 A1
(43) Pub. Date: Dec. 21, 2023

(54) INVERSE DESIGN SYSTEM DESIGNING NANO-OPTICAL DEVICE USING CONTROLLABLE GENERATIVE ADVERSARIAL NETWORK AND TRAINING AND DESIGN METHODS

(71) Applicant: SAMSUNG ELECTRONICS CO., LTD., SUWON-SI (KR)

(72) Inventors: JINSEOK HONG, SUWON-SI (KR); JUNHEE SEOK, SEOUL (KR); WONSUK KIM, SEOUL (KR); KYU IL LEE, SUWON-SI (KR)

(73) Assignee: Korea University Research & Business Foundation, Seoul (KR)

(21) Appl. No.: 17/973,188

(22) Filed: Oct. 25, 2022

(30) Foreign Application Priority Data
Jun. 15, 2022 (KR) 10-2022-0072603

(51) Int. Cl. G06F 30/27

(52) U.S. Cl. CPC G06F 30/27

(57) ABSTRACT

An inverse design system is configured to design a pattern of a structure in an image sensor. The inverse design system may include; a CPU, a RAM loading a controllable Generative Adversarial Network (cGAN), wherein the cGAN is executable by the CPU to generate an image of the structure corresponding to a target characteristic, and an I/O interface receiving a training data set used to train the cGAN, communicating the training data set to the CPU, and outputting the image generated by the cGAN. The cGAN includes a generator generating a fake image of the structure, a discriminator determining whether the fake image is fake or real, and a classifier classifying a class label associated with the fake image and corresponding to the target characteristic.

### CROSS-REFERENCE TO RELATED APPLICATIONS

This application claims priority under 35 U.S.C. § 119 to Korean Patent Application No. 10-2022-0072603 filed on Jun. 15, 2022 in the Korean Intellectual Property Office, the subject matter of which is hereby incorporated by reference in its entirety.

### BACKGROUND

Embodiments of the inventive concept relate generally to machine learning systems, and more particularly, to inverse design systems that may be used to design nano-optical device(s) using a generative allele neural network. Embodiments of the inventive concept also relate to training and designing methods associated with the foregoing.

Inverse design may be understood as a process of designing an appropriate structure exhibiting desired physical properties using an optimization method based on physical properties and/or function(s) of the structure. Thus, in the field of nano-optics, inverse design may be understood as a process of designing a nano-optical structure exhibiting desired optical properties. In the field of nano-optics, inverse design has been investigated since it enables non-intuitive optical structure design by applying various optimization methods such as topology optimization.

With recent developments in data-based, deep learning technology, studies predicting the characteristics of nano-optical structures using deep learning are being actively pursued. Earlier approaches were used to identify optical device design(s) exhibiting desired characteristics using a genetic algorithm and a deep learning model to predict characteristics for various nano-optical structures. However, such approaches must converge upon a predetermined target feature for each iteration, and unfortunately, this requirement drives up computation time and corresponding costs.

### SUMMARY

Embodiments of the inventive concept provide a generative model based on a controllable Generative Adversarial Network (cGAN) capable of efficiently designing a nano-optical device exhibiting desired characteristics based on simulation data. Embodiments of the inventive concept also provide inverse design methods capable of designing various a structure pattern associated with a nano-optical device using a cGAN. Embodiments of the inventive device also provide methods of training an inverse design system using a cGAN in relation to various target characteristics in order to generate a structure pattern associated with a nano-optical device.

In some embodiments the inventive concept provides an inverse design system configured to design a pattern of a structure in an image sensor. The inverse design system includes; a central processing unit (CPU), a random access memory (RAM) configured to load a controllable Generative Adversarial Network (cGAN), wherein the cGAN is executable by the CPU to generate an image of the structure corresponding to a target characteristic, and an input/output (I/O) interface configured to receive a training data set used to train the cGAN, communicate the training data set to the CPU, and output the image generated by the cGAN. The cGAN includes a generator configured to generate a fake image of the structure, a discriminator configured to determine whether the fake image is fake or real, and a classifier configured to classify a class label associated with the fake image and corresponding to the target characteristic.

In some embodiments the inventive concept provides a method of training an inverse design system using a controllable Generative Adversarial Network (cGAN), wherein the inverse design system is driven by a computer system, receives a target characteristic, and generates a structure pattern for a nano-optical device. The method includes; training a discriminator and a classifier of the cGAN using simulation data associated with the nano-optical device, generating a fake image of the structure pattern using a generator of the cGAN by combining the target characteristic and random noise, calculating a discrimination error used to determine whether the fake image is real or fake by providing the fake image to the discriminator, determining a characteristic classification error for the fake image by providing the fake image to the classifier, and competitively training the generator, the discriminator, and the classifier with reference to the discrimination error and the characteristic classification error.

In some embodiments the inventive concept provides an inverse design method for designing a dielectric pattern of an image sensor using a controllable Generative Adversarial Network (cGAN). The method includes; collecting simulation data related to transmittance for each wavelength among a plurality of wavelengths relevant to the dielectric pattern, training a generation model based on the cGAN driven in a computing system using the simulation data to provide a trained generation model, generating a dielectric pattern image by inputting a maximum transmittance wavelength to the trained generation model, and designing the image sensor including the dielectric pattern in accordance with the dielectric pattern image.

### BRIEF DESCRIPTION OF THE DRAWINGS

Various advantages, benefits and features, as well as the making and use of the inventive concept may be understood upon consideration of the following description together with the accompanying drawings, in which:

FIG. 1 is a cross-sectional view illustrating a pixel sensor, as an example of a range of nano-optical devices that may be designed using an inverse design system and method according to embodiments of the inventive concept;

FIG. 2 is a conceptual diagram further illustrating in one example the dielectric layer of FIG. 1;

FIG. 3 is a conceptual diagram generally illustrating an approach to using an inverse design system according to embodiments of the inventive concept;

FIG. 4 is a block diagram illustrating in one example an inverse design system according to embodiments of the inventive concept;

FIG. 5 is a conceptual block diagram illustrating a controllable Generative Adversarial Network (cGAN) according to embodiments of the inventive concept;

FIG. 6 is a flowchart illustrating in one example a method of training a controllable Generative Adversarial Network cGAN according to embodiments of the inventive concept;

FIG. 7 is a flowchart illustrating in one example a method of designing a nano-optical device according to embodiments of the inventive concept; and

FIGS. 8A, 8B and 8C are respective graphs illustrating characteristic reflection accuracy of a dielectric pattern generated using a controllable Generative Adversarial Network (cGAN) in accordance with embodiments of the inventive concept.

### DETAILED DESCRIPTION

Throughout the written description and drawings, like reference numbers and labels are used to denote like or similar elements, components, features and/or method steps.

In certain illustrated embodiments presented hereafter a pixel sensor is described as one example of a broad range of nano-optical devices susceptible to the benefits of the inventive concept. However, those skilled in the art will appreciate that the scope of the inventive concept is not limited to only the illustrated embodiments.

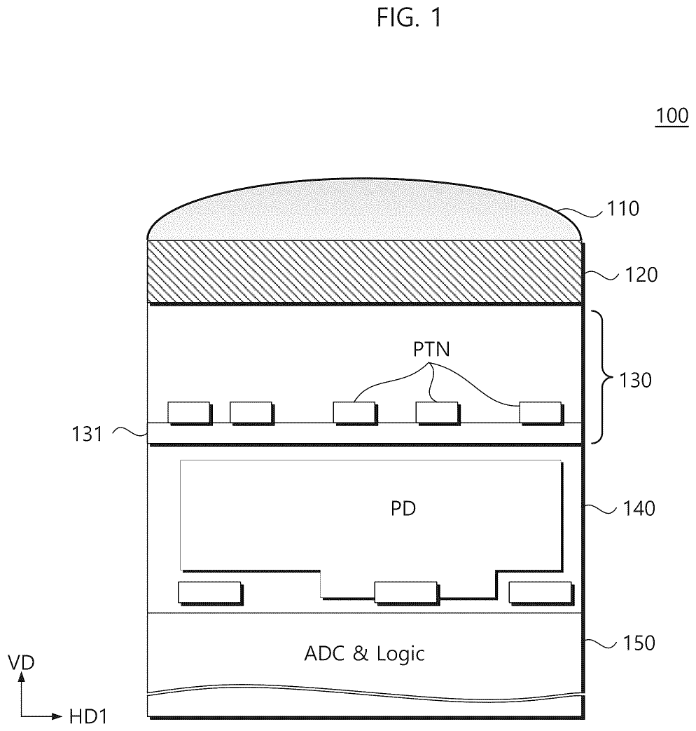

Figure (FIG.) 1 is a cross-sectional view illustrating a pixel sensor designed in accordance with an inverse design method according to embodiments of the inventive concept. Referring to FIG. 1, the pixel sensor 100 may include a number of plate structures vertically stacked (e.g., in a vertical direction VD) one on top of the other, wherein each plate structure principally extends in a horizontal direction (e.g., HD1). Here, each plate structure may be generally associated with one or more elements, components and/or features. For example, the pixel sensor 100 may include a micro lens 110 stacked on a color filter 120, wherein the color filter 120 is stacked on a dielectric layer 130. The dielectric layer 130 is vertically stacked on an upper plate 140, which in turn is vertically stacked on a lower plate 150.

The micro-lens 110 may be used to collect (or focus) electromagnetic energy received from an external source (hereafter, “incident light”). The collected incident light may then be communicated (or passed) to the color filter 120. In some embodiments, the micro lens 110 may include a silicon nitride (SiN) film and/or a silicon oxide (SiO2) film.

The color filter 120 may act as a filter selectively blocking portions of the incident light other than predetermined wavelengths(s) in order to pass only desired portions of the incident light (e.g., visible light). Thus, the color filter 120 may be implemented as any one of a red filter passing only red light, a green filter passing only green light, or a blue filter passing only blue light. Alternately, the color filter 120 may include any one of a cyan filter, a yellow filter, and a magenta filter.

The dielectric layer 130 is formed between the color filter 120 and the photodiode PD of the upper plate 140. Here, the dielectric layer 130 may pass light selected by the color filter 120 to a photodiode PD. The dielectric layer 130 may include a silicon oxide film and/or a silicon nitride film. In some embodiments, the dielectric layer 130 may include a substrate 131 and dielectric patterns (PTN) formed on the substrate 131. For example, the substrate 131 may be formed of a silicon Si substrate, and the dielectric patterns PTN may be formed of a silicon oxide film. However, the configuration of the dielectric layer 130 may be vary by design.

The light transmission characteristics of the dielectric layer 130 may be largely determined by the dielectric pattern PTN of the dielectric layer 130. That is, the characteristics (e.g., intensity and wavelength) of the light passed by the dielectric layer 130 is determined by the physical dimensions of the pattern shapes, the thickness of the pattern shapes, etc. For example, a specific type of dielectric pattern PTN may correspond to a maximum transmittance of a desired wavelength (e.g., 600 nm) or bandwidth. The corresponding dielectric pattern PTN may be obtained in accordance with an image generated by a controllable Generative Adversarial Network (cGAN) as will be described in some additional detail hereafter. In this regard, the “image” generated by the cGAN may be variously expressed as pattern information (or data), image information, a pattern image, structure pattern information, a data structure defining physical dimensions of a structure, etc.

Various elements and/or components associated with the pixel sensor 100, such as a photodiode PD, a floating diffusion region FD, and related transistors may be formed on the upper plate 140. Here, the photodiode PD may be include at least one of an organic material, a quantum dot (QD), a-Si, and a semiconductor material (e.g., a thin film material). The photo-charge accumulated in the photodiode PD may be selectively transferred to the floating diffusion region FD through a structure such as a via and the transfer transistor TX.

Various logic circuits including an analog-to-digital converter (ADC) associated with the pixel sensor may be formed on the lower plate 150.

Of particular note, the pixel sensor 100 described above may include a dielectric pattern PTN designed using a reverse-engineering approach enabled by a computing system using a cGAN. Thus, when desired transmission characteristics for the dielectric layer 130 are applied (or input) to the computing system, a dielectric pattern PTN capable of providing the desired transmission characteristics may be generated in the form of a corresponding image. Of further note, this inverse design method may be applied to not only the design of the dielectric layer 130, but also the design of the color filter 120, or various other nano-optical devices.

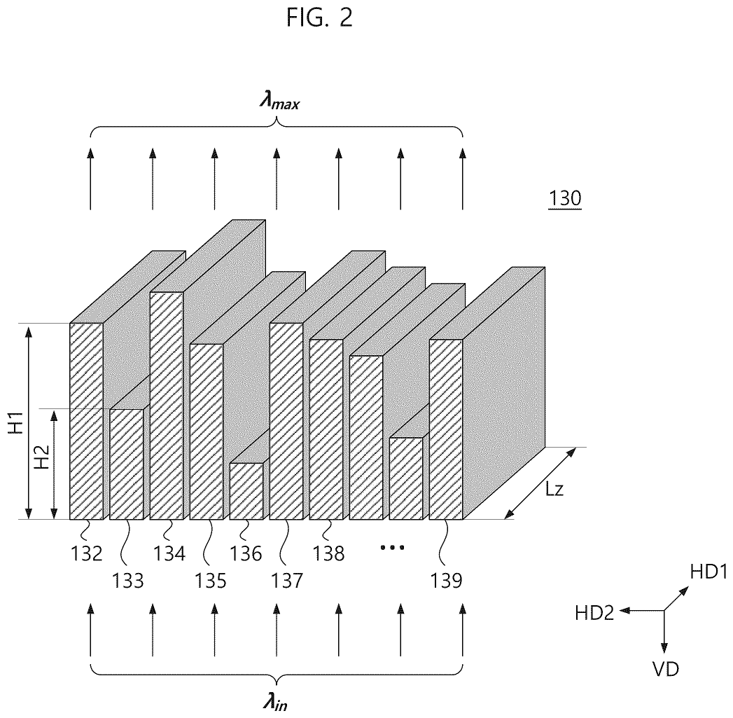

FIG. 2 is a conceptual diagram illustrating an exemplary structure for the dielectric layer 130 of FIG. 1. Referring to FIGS. 1 and 2, the dielectric layer 130 may include the substrate 131 and dielectric patterns 132, 133, 134, 135, 136, 137, 138 and 139 (hereafter, “dielectric patterns 132 to 139”) formed on an upper surface and/or a lower surface of the substrate 131.

The substrate 131 may be include silicon Si, and in FIG. 2 it is assumed that the dielectric patterns 132 to 139 (e.g., silicon oxide films) are respectively formed on the upper surface of the substrate 131. Each of the dielectric patterns 132 to 139 may be formed in a bar shape having a respective length ‘Lz’ extending in a first horizontal direction HD1 and a respective height ‘H’ (e.g., H1 and H2) extending in the vertical direction VD. Although the dielectric patterns 132 to 139 of FIG. 2 are shown as having a bar shape, the dielectric patterns 132 to 139 may have various three-dimensional shapes such as concentric circles or squares. In addition, the thickness of each of the dielectric patterns 132 to 139 in the second horizontal direction HD2 may vary by design.

A wavelength λₘₐₓ having a maximum transmittance among the incident light λᵢₙ may vary according to the shape of the dielectric patterns 132 to 139. The selection of transmittance for each wavelength is determined by the shape of the dielectric patterns 132 to 139. Accordingly, the shape of the dielectric patterns 132 to 139 corresponding to the desired maximum transmittance wavelength λₘₐₓ when designing the nano-optical device is obtained through know-how and/or trial and error. However, according to inverse design methods consistent with embodiments of the inventive concept, the shape of the dielectric patterns 132 to 137 corresponding to the desired maximum transmittance wavelength % max may be effectively and cost-efficiently generated at high speed through the controllable Generative Adversarial Network (cGAN).

To this end, a computing system capable of driving the cGAN according to embodiments of the inventive concept may be trained through transmittance simulation data associated with possible shape(s) of the dielectric patterns 132 to 139. Thereafter, when using the trained controllable Generative Adversarial Network (cGAN), one or more images corresponding to optimal dielectric patterns 132 to 139 may be obtained in relation to a desired maximum transmittance wavelength λₘₐₓ.

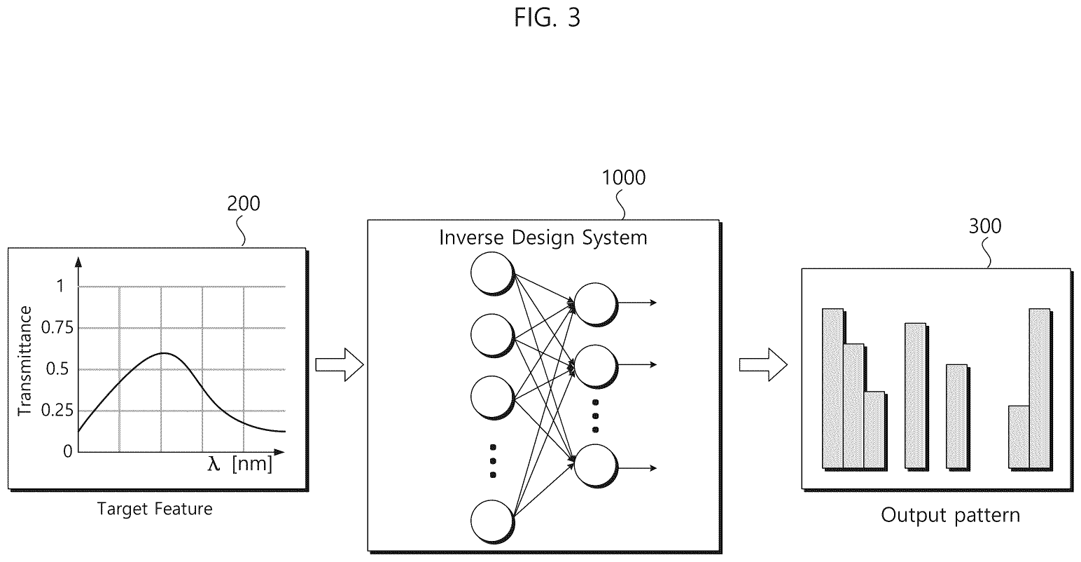

FIG. 3 is a conceptual diagram generally illustrating a methodology approach consistent with embodiments of the inventive concept. Referring to FIG. 3, an inverse design system 1000 may be used to generate an output pattern 300 corresponding to an input target characteristic 200.

Extending the working example of FIGS. 1 and 2, the input target characteristic 200 may be the maximum transmittance wavelength λₘₐₓ associated with the structure to be designed. That is, the target characteristic 200 may correspond to wavelength selection characteristics of dielectric patterns formed on the dielectric layer of the image sensor. However, the target characteristic 200 may be provided with various characteristics as well as the maximum transmittance wavelength λₘₐₓ. For example, a cutoff wavelength characteristic or various physical characteristics may be used as the target characteristic 200.

The inverse design system 1000 may generate an image corresponding to the input target characteristic 200. To this end, the inverse design system 1000 may operate based on a controllable Generative Adversarial Network (cGAN). Here, for example, a controllable Generative Adversarial Network (cGAN) contemplated by the inventive concept may include a discriminator, a generator, and a classifier, wherein the discriminator, generator, and classifier may be used to perform training competitively based on device design samples and characteristic information. Further in this regard, a structure design or structure pattern having a target feature may be generated using the controllable Generative Adversarial Network (cGAN) after training. An exemplary training procedure for the controllable Generative Adversarial Network (cGAN) and a method generating the structure having the target characteristic through the trained controllable Generative Adversarial Network (cGAN) will be described hereafter in some additional detail.

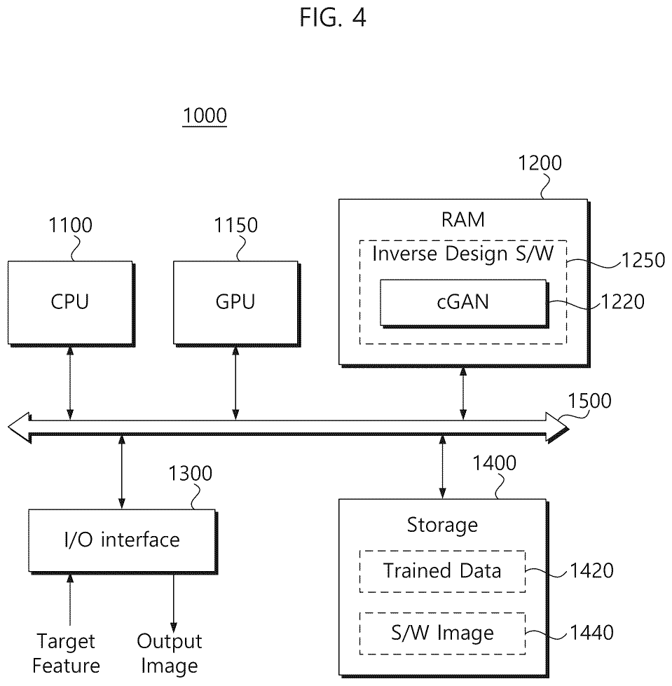

FIG. 4 is a block diagram illustrating in one example hardware that may be used to implement an inverse design system 1000 according to embodiments of the inventive concept. Referring to FIG. 4, the inverse design system 1000 may include a Central Processing Unit (CPU) 1100, a Graphics Processing Unit (GPU) 1150, a Random Access Memory (RAM) 1200, an Input/Output (I/O) interface 1300, a storage 1400, and a system bus 1500. Here, the inverse design system 1000 may be configured as a dedicated device for executing the controllable Generative Adversarial Network cGAN model in accordance with embodiments of the inventive concept. Alternately, the inverse design system 1000 may be a computer or a workstation running a design or simulation program, such as Technology Computer-Aided Design (TCAD) or Electronic Computer-Aided Design (ECAD).

The CPU 1100 may be used to execute various software such as application programs, operating systems, and device drivers associated with operation of the inverse design system 1000. For example, the CPU 1100 may execute an operating system OS loaded into the RAM 1200, and one or more application program(s) using the operating system OS. In this regard, the CPU 1100 may execute the inverse design software 1250 loaded into the RAM 1200.

Here, for example, the inverse design software 1250 may include a controllable Generative Adversarial Network (cGAN) associated with a neural network structure including a discriminator, a generator, and a classifier. The CPU 1100 may train the controllable Generative Adversarial Network (cGAN) by driving of the inverse design software 1250 together with the GPU 1150, an example of which is described hereafter in some additional detail. In addition, the CPU 1100 may generate an output pattern or an output image corresponding to target characteristic(s) input through the trained controllable Generative Adversarial Network (cGAN).

The GPU 1150 may be used to execute various graphic operations or parallel processing operations. In this regard, the GPU 1150 is assumed to have an advantageous structure enabling the efficient, high-speed, repeated execution of parallel operations. In some embodiments, the GPU 1150 may be a general purpose GPU (GPGPU). In addition to video encoding, the GPGPU can be used to perform various operations commonly associated with molecular structure analysis, crypto-analysis, and weather predictive analysis, etc. In this regard, the GPU 1150 of FIG. 4 should be capable of performing an efficient training (or modeling) operations in relation to the controllable Generative Adversarial Network (cGAN).

The operating system OS and/or various application programs may be stored in the RAM 1200. That is, when the inverse design system 1000 is initially booted, the OS image stored in the storage 1400 will be loaded into the RAM 1200 in accordance with a booting sequence. Certain I/O operations associated with the inverse design system 1000 may be supported by the operating system OS. Similarly, application programs may be loaded into the RAM 1200, wherein the various application programs may be selected by a user. In particular, the inverse design software 1250 will loaded into the RAM 1200 from the storage 1400.

Here, the RAM 1200 may be implemented using volatile memory such as a static RAM (SRAM) and/or a dynamic RAM (DRAM), and/or nonvolatile memory, such as a Phase-change RAM (PRAM), magnetic RAM (MRAM), resistive RAM (ReRAM), ferromagnetic RAM (FRAM), and flash memory (e.g., NAND flash or NOR flash).

Within the foregoing exemplary configuration, the inverse design software 1250 supports an inverse design method using the controllable Generative Adversarial Network (cGAN) 1220. For example, the controllable Generative Adversarial Network (cGAN) used in relation to the inverse design software 1250 may be trained using a relatively large quantity of simulation data (hereafter, “simulation data”) related to one or more nano-optical devices and/or structure(s) and/or pattern(s) associated with the one or more nano-optical device(s). Of further note, the simulation data may include data samples taken in relation to both fake images and real images associate with the one or more nano-optical devices and/or structure(s) and/or pattern(s) associated with the one or more nano-optical device(s). That is, a significant quantity of simulation data associated with designing the dielectric pattern(s) of the dielectric layer 130 of FIGS. 1 and 2 may be used to train the controllable Generative Adversarial Network (cGAN) 1220, as well as various components of the cGAN 1220.

The nature, composition and size of the simulation data may vary by application and design, but will include certain data related to one or more physical properties, such as maximum transmittance wavelength λₘₐₓ and/or a cutoff wavelength for a specific dielectric pattern. Thus, the simulation data includes characteristic data for a relatively large number of dielectric patterns that may be characterized through simulation. In addition, the simulation data may also include characteristic information related to the color filter 120 of FIG. 1, as well as meta lens, meta prisms, etc.

When the training of the controllable Generative Adversarial Network (cGAN) 1220 has been fully trained, the CPU 1100 may generate an output image corresponding to a target feature input through the I/O interface 1300. That is, the CPU 1100 may generate an output image of a structure corresponding to a target feature using the trained, controllable Generative Adversarial Network (cGAN) 1220. For example, when the maximum transmittance wavelength λₘₐₓ is provided as a target characteristic, the trained, controllable Generative Adversarial Network (cGAN) 1220 may generate a corresponding dielectric pattern in the form of a corresponding image.

In some embodiments, in order to provide the foregoing features, the controllable Generative Adversarial Network 1220 may include three neural network structures: a discriminator, a generator, and a classifier. The generator may receive a class label vector and a noise vector of a specific condition as inputs and generate a fake image belonging to the class label as an output. Then, the discriminator may compare the fake image generated by the generator with the real image to calculate a probability that it is either fake or real. During the training process, the discriminator may receive a real image associated with a training data set and a corresponding class label as input and outputs indicating a probability that the image is real. The classifier may receive the training data set and the fake image generated from the generator and a class label corresponding thereto, and output a class label of the fake image. One more specific example of a training process or image generation process using the controllable Generative Adversarial Network (cGAN) 1220 will be described hereafter in some additional detail.

The I/O interface 1300 may be used to control user inputs and/or outputs related to various user interface devices. For example, the I/O interface 1300 may include a keyboard and mouse receiving user inputs, and/or a monitor communicating information to the user. Target data used to train the inverse design software 1250 may also be provided through the I/O interface 1300. In addition, the I/O interface 1300 may display progress or processing results during training or pattern generation operation of the inverse design system 1000.

The storage 1400 may generally be used as a storage medium associated with the inverse design system 1000. In this regard, the storage 1400 may store various application programs and/or operating system image(s), a software image 1440 of inverse design software, and various data. In addition, the storage 1400 may store and update the trained data 1420 according to the operation of the inverse design software 1250. The storage 1400 may be variously implemented and may include at least one of a memory card (MMC, eMMC, SD, MicroSD, etc.), solid-state drive (SSD) and/or hard disk drive (HDD). In some embodiments, the storage 1400 may include at least one of NAND flash memory, NOR flash memory, PRAM, MRAM, ReRAM, and/or FRAM.

The system bus 1500 may be variously implemented to interconnect components of the inverse design system 1000 (e.g., CPU 1100, GPU 1150, RAM 1200, I/O interface 1300, and the storage 1400). In some embodiments, the system bus 1500 may further include a bus arbiter to improve data management.

Consistent with the foregoing, the inverse design system 1000 may perform an inverse design operation that generates an output image associated with target feature(s) according to operation of the inverse design software 1250. In particular, the inverse design software 1250 may generate an image of a structure pattern satisfying target feature(s) using a controllable Generative Adversarial Network (cGAN) 1220 that has been trained using simulation data. In this manner, the inverse design system 1000 of FIG. 4 may be used to design a pattern of a nano-optical device having desired characteristics at high speed, with improved accuracy, and at reduced cost.

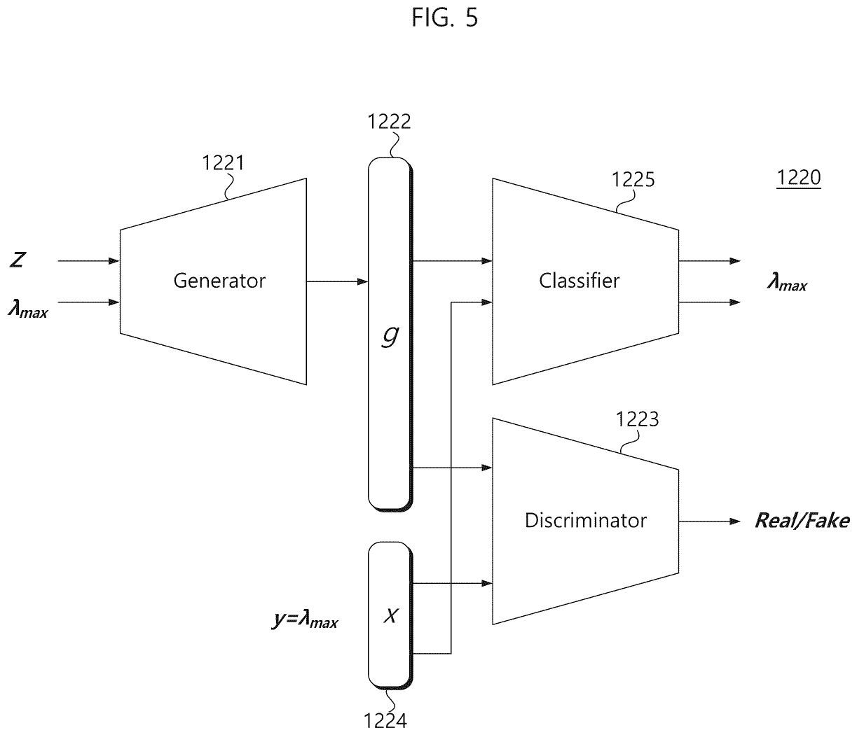

FIG. 5 is a block diagram further illustrating in one example the controllable Generative Adversarial Network (cGAN) 1220 of FIG. 4 according to embodiments of the inventive concept. Here, the controllable Generative Adversarial Network (cGAN) 1220 includes a generator 1221, a discriminator 1223, and a classifier 1225.

The generator 1221 is configured to receive random (or white) noise Z and a class label vector (e.g., the maximum transmittance wavelength λₘₐₓ) and generate a fake image 1222. The fake image 1222 may then be respectively evaluated by the discriminator 1223 and the classifier 1225. For training of the generator 1221, a determination result generated by the discriminator 1223 and a classification result generated by the classifier 1225 used as feedback data. In effect, the generator 1221 uses the random noise Z (e.g., one or more samples of the random noise Z) and the class label vector λₘₐₓ to perform training in order to generate a fake image substantially similar (or “like”) the real image. For example, various weighting(s) may be applied to the neural network associate with the generator 1221 during training. Further, the class label vector λₘₐₓ derived from the simulation data related to one or more nano-optical device(s), as well as the feedback data may be provided to the neural network associated with the generators 1221.

Accordingly, a generator loss function LG associated with training of the generator 1221 may be expressed by Equation 1, below:

L_{G}=−E_{z˜p}_{_{z}}D(G(z|y))+yₜE_{z˜p}_{_{z}}C(G(z|y),y) [Equation 1]

Here, ‘Ez˜p_{z}’ is the expected value, wherein ‘z˜p_{z}’ denotes the random noise samples extracted from the noise data distribution; D(G(zly)) is a conditional probability that ‘y’ is determined to be true by the discriminator 1223; ‘γt’ is a trainable variable initialized to ‘0’ and indicating an appropriate weight given to the input class of the generator; and ‘C(G(z|y), y)’ denotes a conditional probability indicating whether the property of ‘y’ is met by the classifier 1225.

Under the foregoing conditions, the generator 1221 may be used to generate a fake image ‘g’ by adding a desired characteristic ‘y’ (e.g., the class label vector λₘₐₓ) to the randomly selected samples of the random noise Z. In addition, the generator 1221 may be trained in a direction to minimize the generator loss function L_{G}.

The discriminator 1223 receives the fake image ‘g’ generated by the generator 1221 and determines whether it is a real image or a fake image. If a real image 1224 is input to the discriminator 1223, the discriminator 1223 will determine that is a real image. However, the determination of real verses fake identified by the discriminator 1223 may vary depending on the accuracy (or precision) of the input fake image 1222. In this manner, the generator 1221 may be trained in a direction to generate the fake image 1222, such that the discriminator 1223 determines it to be real. Alternately or additionally, the discriminator 1223 may be competitively trained to discriminate the fake image 1222 generated by the generator 1221 as a fake.

Accordingly, a discriminator loss function L_{D} associated with training of the discriminator 1223 may be expressed by Equation 2 below:

L_{D}=−E_{x˜p}_{_{data}}[min(0,−1+D(x|y))]−E_{z˜p}_{_{z}}[min(0,−1−D(G(z|y)))]+λE_{x′˜p}_{_{x′}}[(∥∇_{x′}D(x′|y)∥₂−1)²] [Equation 2]

Here, ‘x˜p_{data}’ denotes sample(s) extracted from a real data distribution; ‘z-p_{z}’ denotes noise sample(s) extracted from a noise data distribution; ‘y’ indicates the class label corresponding to each sample; ‘x’-pₓ″ denotes model distribution(s) extracted from the uniform distribution; and ‘λ’ denotes a degree of gradient penalty. In this regard, the neural network associated with the discriminator 1223 may be trained to classify real data as ‘1’ and fake data as ‘0’ in relation to the discriminator loss function L_{D}.

Finally, the value, λE_{x′˜p}_{_{x′}}[(∥∇_{x′}D(x′|y)∥₂−1)²], of Equation 2 is provided as a gradient penalty for stabilizing the training gradient of the discriminator. Accordingly, training results may be obtained in the direction of reducing the gradient penalty of the discriminator loss function L_{D}. That is, the neural network weights of the discriminator 1223 may be trained in a direction in which the error slope ∇x′D(x′|y) of the value output from the discriminator 1223 is not significantly different from ‘1’ by the gradient penalty of the discriminator loss function L_{D}.

The classifier 1225 receives a training data set, fake image 1222 generated from the generator 1221, and a corresponding class label vector λₘₐₓ. With these inputs, the classifier 1225 may classify the class label of the image and output corresponding a classification result. A classifier loss function L_{C} for training of the classifier 1225 may be expressed by Equation 3 below:

L_{C}=−E_{x˜pdata}C(x,y) [Equation 3]

Here, ‘ Ex pdata’ denotes an expected value, and C(x, y) denotes a conditional probability indicating whether the characteristic of ‘y’ provided by the generator 1221 is classified as an actual image ‘x’. The training of the classifier 1225 may proceed in the direction reducing the classifier loss function LC. That is, the training of the classifier 1225 proceeds in the direction of increasing accuracy with which a given fake image 1222 is classified into the class label vector λₘₐₓ.

With the foregoing controllable Generative Adversarial Network (cGAN) 1220 in mind, certain embodiments of the inventive concept may provide feature class information an input of the generator 1221, as derived as an output of the classifier 1225. Accordingly, the generator 1221 may include a deconvolutional layer serving as a decoder, whereas the classifier 1225 may include a convolutional layer serving as an encoder.

An Adaptive Moment Estimation (ADAM) optimization algorithm may be used to further optimize the neural network variables of the generator 1221, discriminator 1223, and classifier 1225 of the controllable Generative Adversarial Network (cGAN) 1220. In addition, the conventionally understood “Two Time-scale Update Rule” (hereafter, “TTUR”) may be used to select a training rate. Depending on the application of TTUR, the generator 1221 may be trained over several iterations (or steps) according to a more detailed training rate, so as to better fool the discriminator 1223.

In addition, several normalization methods may be applied to stabilize the adversarial training of the controllable Generative Adversarial Network (cGAN) 1220. For example, a gradient penalty may be applied to stabilize a training gradient, as suggested by Equation 1. In addition, conditional batch normalization and layer normalization may be used in associated with the generator 1221 and the classifier 1225. Spectral normalization may be used in the generator 1221 and the discriminator 1223. In addition, a hinge loss function may be used to stabilize training of the discriminator 1223.

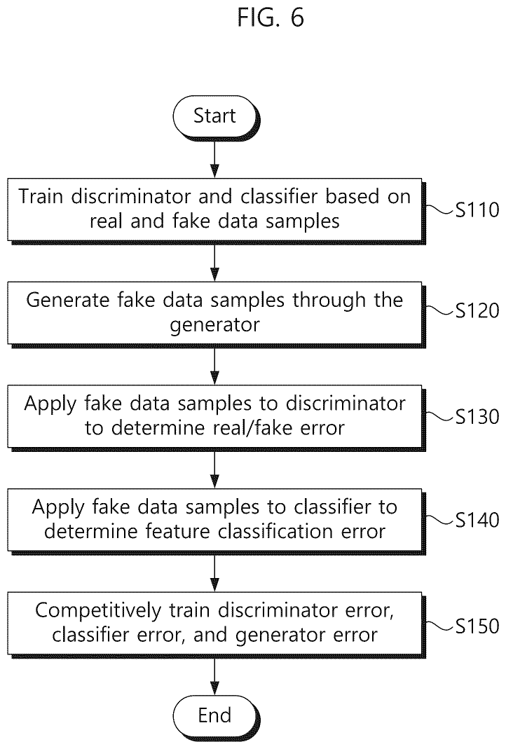

FIG. 6 is a flowchart illustrating in one example a method of training the controllable Generative Adversarial Network (cGAN) 1220 of the inverse design system 1000 of FIG. 4 according to embodiments of the inventive concept. Referring to FIG. 6, simulation data accumulated during design process(es) for nano-optical device(s) may be used to develop a training data set for competitive training of the controllable Generative Adversarial Network (cGAN) 1220.

Accordingly, the discriminator 1223 and the classifier 1225 may be trained in accordance with the simulation data provided to the inverse design system 1000 (S110). For example, characteristic information (e.g., maximum transmittance wavelength λₘₐₓ) associated with the nano-optical device in the simulation data and dielectric pattern information corresponding thereto may be used to train the discriminator 1223 and the classifier 1225.

Thereafter, a fake data sample may be generated by the generator 1221 (S120). Here, the generator 1221 may generate the fake data sample in response to the random noise (Z) and the characteristic information (e.g., the maximum transmittance wavelength λₘₐₓ). The fake data sample may be, for example, a dielectric pattern associated with a nano-optical device. In addition, the generator 1221 may determine a generation error (e.g., a generator loss function).

The discriminator 1223 may then determine a discrimination error (e.g., a discriminator loss function) by comparing the fake data sample generated by the generator 1221 with the real data sample (e.g., a real dielectric pattern) (S130). Here, the discrimination error may have a relatively small value when the fake data sample is do substantially similar to the real data sample that proper identification as fake is difficult.

The classifier 1225 may classify the fake data sample generated by the generator 1221 to determine a characteristic classification error (e.g., a classifier loss function) (S140).

Then, the generator 1221, discriminator 1223, and classifier 1225 may perform competitive training using the generation error, discrimination error, and characteristic classification error (S150). here, a conditional batch normalization and a layer normalization may be applied to the generator 1221 and the classifier 1225 in order to reduce the training time and increase the training performance. In addition, spectral normalization may be applied to the competitive training of the generator 1221 and the discriminator 1223. In addition, in the training of the discriminator 1223, a hinge loss may be used to promote training stabilization.

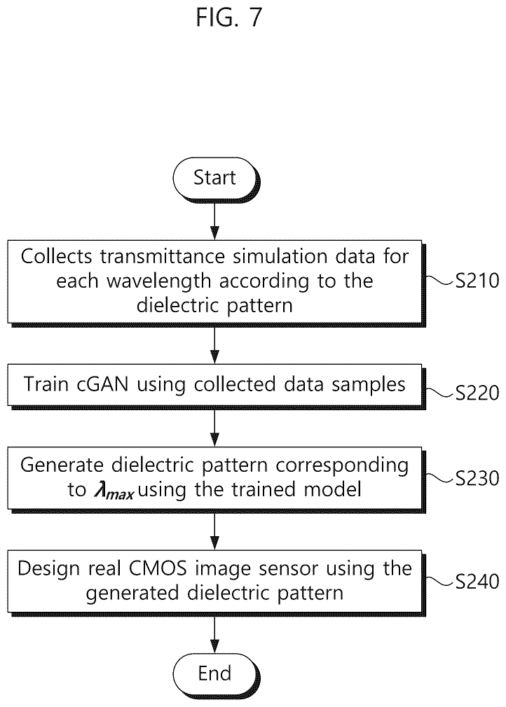

FIG. 7 is a flowchart illustrating in one example a method of designing a nano-optical device according to embodiments of the inventive concept. Here, the method of FIG. 7 assumes the design of a dielectric pattern for a Complementary Metal Oxide Semiconductor (CMOS) image sensor through the inverse design system 1000.

Accordingly, transmittance data for each wavelength relevant to the dielectric pattern of the image sensor may be collected (S21). For example, simulation data for each wavelength of the dielectric pattern of the image sensor may be collected. The simulation data for each wavelength of the dielectric pattern may include a considerable quantity of data obtained through various experiments and/or device testing.

Then, training of the controllable Generative Adversarial Network (cGAN) 1220 of the inverse design system 1000 may be performed using the simulation data (e.g., various data samples) (S220). Training of the controllable Generative Adversarial Network (cGAN) 1220 may be performed for each of the generator 1221, discriminator 1223, and classifier 1225. For example, training of the controllable Generative Adversarial Network (cGAN) 1220 may proceed in accordance with the method of FIG. 6.

Thereafter, the dielectric pattern may be generated using the trained controllable Generative Adversarial Network (cGAN) 1220 (S230). For example, assuming that a maximum transmittance wavelength λₘₐₓ is applied as an input to the generator 1221 of the trained controllable Generative Adversarial Network (cGAN) 1220, a corresponding dielectric pattern may be generated as an image.

Thereafter, a CMOS image sensor including the dielectric pattern may be designed in relation to the maximum transmittance wavelength λₘₐₓ. In this regard, the dielectric pattern will provide a transmittance characteristic consistent with the maximum transmittance wavelength λₘₐₓ for the resulting CMOS image sensor.

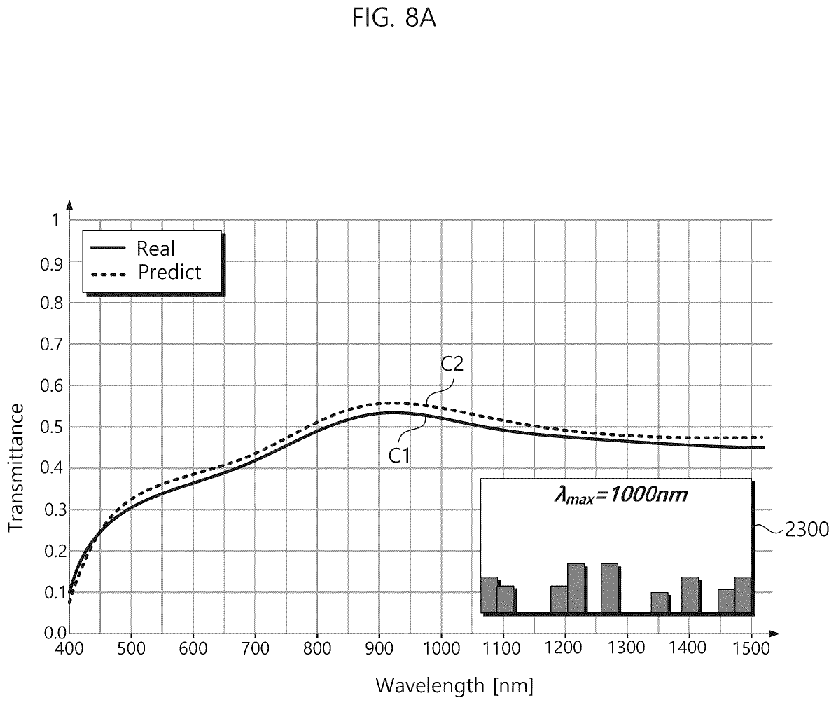

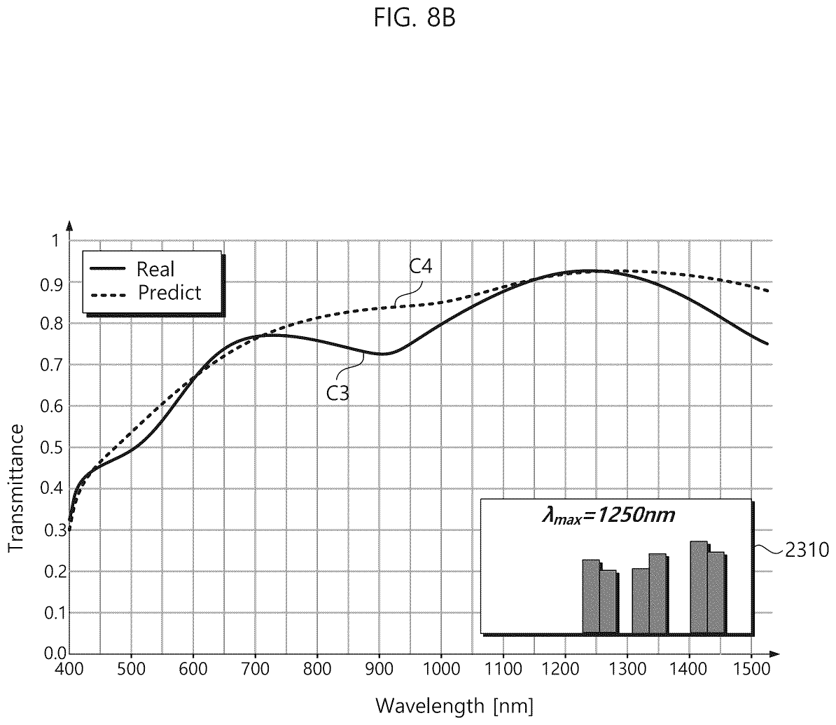

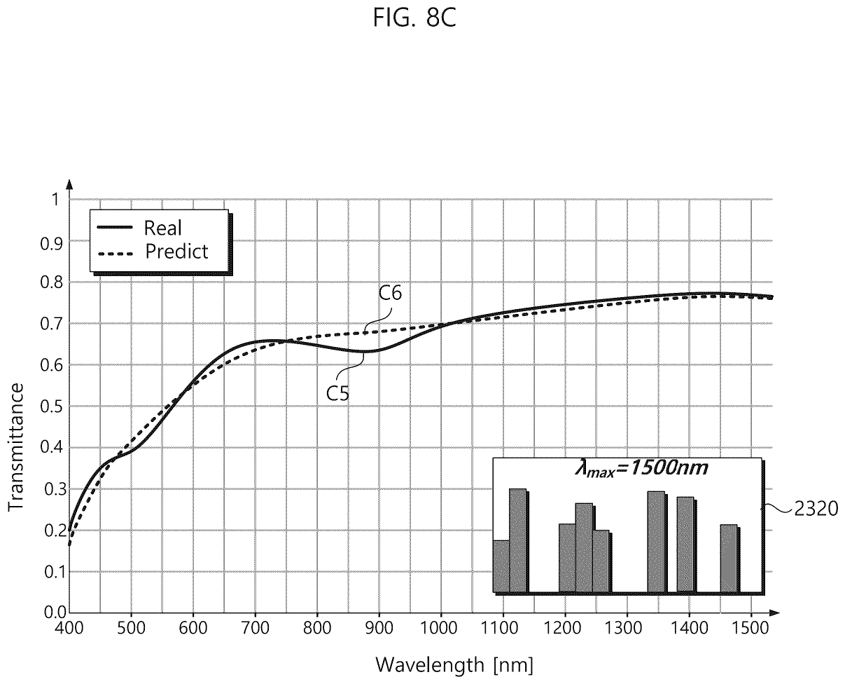

FIGS. 8A, 8B and 8C are respective graphs illustrating characteristic accuracy of a dielectric pattern generated using a controllable Generative Adversarial Network (cGAN) according to embodiments of the inventive concept.

Referring to FIG. 8A, a dielectric pattern 2300 may be generated by inputting a maximum transmittance wavelength λₘₐₓ of 1000 nm as a target characteristic, an actual simulation result C1, and a simulation result C2 of a prediction model based on a convolutional layer. Simulation results for an image sample of the dielectric pattern 2300 designed using the controllable Generative Adversarial Network (cGAN) indicate that the target characteristics are accurately represented.

Referring to FIG. 8B, an actual simulation result C3 for a dielectric pattern 2310 may be generated by inputting a maximum transmittance wavelength λₘₐₓ of 1250 nm as a target characteristic and a simulation result C4 of a prediction model based on a convolutional layer. Simulation results for an image sample of the dielectric pattern 2310 designed using the controllable Generative Adversarial Network (cGAN) indicate that the target characteristics are accurately represented.

Referring to FIG. 8C, a dielectric pattern 2320 may be generated by inputting a maximum transmittance wavelength λₘₐₓ of 1500 nm as a target characteristic, an actual simulation result C5, and a simulation result C6 of a prediction model based on a convolutional layer. Simulation results of the image sample of the dielectric pattern 2320 designed using a controllable Generative Adversarial Network (cGAN) indicate that the target characteristics are accurately represented.

While the inventive concept has been described with reference to certain illustrated embodiments, those skilled in the art will appreciate that various changes and modifications may be made thereto without departing from the scope of the inventive concept, as defined by the following claims.

What is claimed is:

1. An inverse design system configured to design a pattern of a structure in an image sensor, the inverse design system comprising:
a central processing unit (CPU);
a random access memory (RAM) configured to load a controllable Generative Adversarial Network (cGAN), wherein the cGAN is executable by the CPU to generate an image of the structure corresponding to a target characteristic; and
an input/output (I/O) interface configured to receive a training data set used to train the cGAN, communicate the training data set to the CPU, and output the image generated by the cGAN,
wherein the cGAN includes a generator configured to generate a fake image of the structure, a discriminator configured to determine whether the fake image is fake or real, and a classifier configured to classify a class label associated with the fake image and corresponding to the target characteristic.

2. The system of claim 1, wherein the generator is further configured to combine the class label with random noise to generate the fake image.

3. The system of claim 1, wherein the discriminator if further configured to operate in response to a discriminator loss function including a gradient penalty to stabilize weights during training of the cGAN.

4. The system of claim 1, wherein the classifier is further configured to generate a classification result for the fake image, and
the classification result is feedback data applied to the generator during training of the generator.

5. The system of claim 1, wherein at least one of the generator and the discriminator is trained using at least one of conditional batch normalization and layer normalization.

6. The system of claim 1, wherein at least one of the generator and the discriminator is trained using spectral normalization.

7. The system of claim 6, wherein the discriminator is trained using a hinge loss function.

8. The system of claim 1, wherein the structure is a dielectric pattern formed in a dielectric layer of the image sensor, and the target characteristic is a maximum transmittance wavelength λₘₐₓ of the dielectric layer.

9. A method of training an inverse design system using a controllable Generative Adversarial Network (cGAN), wherein the inverse design system is driven by a computer system, receives a target characteristic, and generates a structure pattern for a nano-optical device, the method comprising:
training a discriminator and a classifier of the cGAN using simulation data associated with the nano-optical device;
generating a fake image of the structure pattern using a generator of the cGAN by combining the target characteristic and random noise;
calculating a discrimination error used to determine whether the fake image is real or fake by providing the fake image to the discriminator;
determining a characteristic classification error for the fake image by providing the fake image to the classifier; and
competitively training the generator, the discriminator, and the classifier with reference to the discrimination error and the characteristic classification error.

10. The method of claim 9, wherein the structure pattern is a dielectric pattern formed in a dielectric layer of the nano-optical device.

11. The method of claim 10, wherein the target characteristic is a maximum transmittance wavelength of light transmitted through the dielectric pattern.

12. The method of claim 9, wherein a gradient of the discrimination error is limited by applying a discriminator loss function having a gradient penalty term when training the discriminator.

13. The method of claim 9, wherein the competitively training of the generator, the discriminator, and classifier includes using an Adaptive Moment Estimation optimization algorithm to optimize neural network weightings.

14. The method of claim 13, wherein the competitively training of the generator, the discriminator, and classifier includes using a Two Time-scale Update Rule to stabilize the competitively training of the generator and the discriminator.

15. The method of claim 9, wherein the competitively training of the generator, the discriminator, and classifier includes using one of conditional batch normalization and hierarchical normalization during the competitively training of the generator and the discriminator.

16. An inverse design method for designing a dielectric pattern of an image sensor using a controllable Generative Adversarial Network (cGAN), the method comprising:
collecting simulation data related to transmittance for each wavelength among a plurality of wavelengths relevant to the dielectric pattern;
training a generation model based on the cGAN driven in a computing system using the simulation data to provide a trained generation model;
generating a dielectric pattern image by inputting a maximum transmittance wavelength to the trained generation model; and
designing the image sensor including the dielectric pattern in accordance with the dielectric pattern image.

17. The method of claim 16, wherein the generation model comprises:
a generator configured to generate a fake image by combining a class label and random noise;
a discriminator configured to calculate a discrimination error for determining whether the fake image is real or fake; and
a classifier configured to calculate a characteristic classification error for the fake image generated by the generator.

18. The method of claim 17, wherein the generator, the discriminator, and the classifier are competitively trained in accordance with the discrimination error and the characteristic classification error during the training of the generation model.

19. The method of claim 18, wherein during the training of the generation model, the discriminator applies a gradient penalty to a discriminator loss function to stabilize weightings.

20. The method of claim 17, wherein during the training of the generation model, an adaptive moment estimation optimization algorithm is used to optimize neural network weightings of at least one of the generator, the discriminator and the classifier.
